(19) United States
(12) Patent Application Publication
(10) Pub. No.: US 2026/0360399 A1
(43) Pub. Date: Nov. 12, 2026

(54) STORAGE REGISTER HAVING REDUNDANT NON-VOLATILE BIT CELLS AND METHOD OF OPERATION

(71) Applicant: IM2 Solutions, Inc., Pleasanton, CA (US)

(72) Inventors: Tim LAO, Sacramento, CA (US); Adrian ONG, Pleasanton, CA (US); Nicholas van Heel, Colfax, CA (US)

(21) Appl. No.: 19/672,769

(22) Filed: May 11, 2026

Related U.S. Application Data
(60) Provisional application No. 63/803,921, filed on May 11, 2025.

(51) Int. Cl. G11C 11/16

(52) U.S. Cl. CPC G11C 11/1673; G11C 11/1659; G11C 11/1675; G11C 11/1697

(57) ABSTRACT

Certain embodiments of the present disclosure provide a non-volatile (NV) memory comprising a plurality of bit cell blocks arranged in at least one row and a plurality of columns. To protect against write failures, each bit cell block of the plurality of bit cell blocks includes a plurality of redundant bit cells to store a single data bit having a bit value of “1” or “0”. When writing to the NV cell block, a same data is written to each of the plurality of bit cells in a bit cell block. When reading, a weighted sum of a plurality of branch currents through the plurality of bit cells is used in a current sense amplifier to detect the single bit stored in the NV cell block. Thus, even in the case that writing to some of the bit cells has failed, the single bit data stored in the NV cell block can still be correctly read.

### CROSS REFERENCE TO RELATED APPLICATIONS

The present application is a nonprovisional of U.S. Provisional Application No. 63/803,921, filed May 11, 2025, and is related to U.S. patent application Ser. No. 19/253,872, filed Jun. 29, 2025, U.S. patent application Ser. No. 19/363,553, filed Oct. 20, 2025, and U.S. patent application Ser. No. 19/572,853, filed Mar. 19, 2026. Each of above-referenced patent applications is incorporated herein by reference in its entirety.

### TECHNICAL FIELD

The present application is related to memory devices, and more particularly to a storage register having redundant non-volatile bit cells and method of operation.

### BACKGROUND

The probability of write failures in Spin-Transfer Torque Magnetoresistive Random Access Memory (STT-MRAM) cells depend on the write process and the stochastic behavior of the Magnetic Tunnel Junction (MTJ) structures in the STT-MRAM cells. Some process can have very high write error rate (WER). Therefore, the probability of a write failure in STT-MRAM cells can be high.

### SUMMARY

Certain embodiments of the present disclosure provide a non-volatile (NV) memory comprising a plurality of bit cell blocks arranged in at least one row and a plurality of columns. To protect against write failures, each bit cell block of the plurality of bit cell blocks includes a plurality of redundant bit cells to store a single data bit having a bit value of “1” or “0”.

The non-volatile (NV) memory further comprises a plurality of read sense amplifiers, a respective read sense amplifier of the plurality of read sense amplifiers including a current sense amplifier coupled to each bit cell block in a respective column of the plurality of columns. In an operation to read a bit value stored in one bit cell block in the respective column, the respective current sense amplifier is operable to source a current corresponding to a sum of a plurality of branch currents through respective ones of a plurality of bit cells in the one bit cell block.

In some implementation examples, each bit cell of the plurality of bit cells includes a True cell and a Complement cell, and the respective current sense amplifier includes a first common stage amplifier operable to source a first current corresponding to a sum of a first plurality of branch currents through respective ones of a plurality of True cells in the one bit cell block and a second common stage amplifier operable to source second current corresponding to a sum of a second plurality of branch currents through respective ones of a plurality of Complement cells in the one bit cell block. The respective current sense amplifier is further configured to convert the first current and the second current into differential voltage outputs that are used to determine the bit value stored in the one bit cell block.

In some implementation examples, each bit cell in the respective bit cell block includes a complementary pair of Magnetoresistive Random Access Memory (MRAM) cells, the complementary pair of MRAM cells including a True MRAM cell and a Complement MRAM cell, each MRAM cell of the True MRAM cell and Complement MRAM cell including a Magnetic Tunnel Junction (MTJ) structure and a select transistor coupled in series. When writing to the bit cell block, the same data is written to each of the plurality of bit cells. When reading, the weighted sum of currents through respective cells of a plurality of MRAM cells is used to detect the single bit stored in the bit cell block. Thus, even in the case that writing to some of the MRAM cells has failed, the single bit stored in the bit cell block can still be read correctly.

In some implementation examples, a non-volatile memory comprises an array of bit cell blocks organized in at least one row and a plurality of columns, each bit cell block configured to store one data bit having a bit value of “1” or “0,” a word line coupled to each row of the array of bit cell blocks, a plurality of pairs of bit lines corresponding, respectively, to the plurality of columns of bit cell blocks, each pair of bit lines of the plurality of pairs of bit lines including a True bit line and a complementary bit line, and a plurality of pairs of source lines corresponding, respectively, to the plurality of columns of bit cell blocks, each pair of source lines of the plurality of pairs of source lines including a True source line and a complementary source line.

In some implementation examples, a respective bit cell block of the array of bit cell blocks is coupled to a respective pair of bit lines of the plurality of pairs of bit lines and to a respective pair of source lines of the plurality of pairs of source lines. Each bit cell in the respective bit cell block includes a complementary pair of Magnetoresistive Random Access Memory (MRAM) cells, the complementary pair of MRAM cells including a True MRAM cell and a Complement MRAM cell, each MRAM cell of the True MRAM cell and Complement MRAM cell including a Magnetic Tunnel Junction (MTJ) structure and a select transistor coupled in series.

In some implementation examples, the select transistor in each of the plurality of MRAM cells has a control terminal coupled to a word line, each of the number of True MRAM cells is coupled between the True source line of the respective pair of source lines and the True bit line of the respective pair of bit lines, and each of the number of complementary MRAM cells is coupled between the complementary source line of the respective pair of source lines and the complementary bit line of the respective pair of bit lines.

In some implementation examples, the non-volatile memory further comprises a plurality of write drivers corresponding, respectively, to columns of bit cell blocks in the array of bit cell blocks. A respective write driver of the plurality of write drivers is coupled to the respective bit cell block via the respective pair of bit lines and the respective pair of source lines.

In some implementation examples, the respective current sense amplifiers is coupled to the respective write driver via a pair of global bit lines, and wherein the respective current sense amplifier is operable to source the current that is the sum of currents through respective ones of the plurality of bit cells of the one bit cell block via a corresponding global bit line and the respective write driver. The respective read sense amplifier further includes a respective voltage sense amplifier coupled to the respective current sense amplifier and configured to amplifier the differential voltage outputs and to output amplified differential voltage outputs. The respective read sense amplifier further includes a respective latch and inverter driver circuit configured to convert the amplified differential voltage outputs into a digital bit value of “1” or “0”

In some implementation examples, a respective MRAM cell of the True MRAM cell and Complement MRAM cell has a first state or a second state depending on whether the MTJ structure in the respective MRAM cell has a first resistance state or a second resistance state. The respective read sense amplifier is configured to sense the respective bit cell block as storing a data value of “0” in each of a first case and a second case. In the first case, the True MRAM cell in each bit cell of the respective bit cell block has the first state and the Complement MRAM cell in each bit cell of the respective bit cell block has the second state. In the second case, True MRAM cells in a majority of the plurality of bit cells have the first state and Complement MRAM cells in a corresponding majority of the plurality of bit cells have the second state, while the True MRAM cell in at least one of the plurality of bit cells has the second state and the Complement MRAM cell in the at least one of the plurality of bit cells has the first state.

In some implementation examples, the respective read sense amplifier is further configured to sense the respective bit cell block as storing a data value of “1” in each of a third case and a fourth case. In the third case, the True MRAM cell in each bit cell of the respective bit cell block has the second state and the Complement MRAM cell in each bit cell of the respective bit cell block has the first state. In the fourth case, True MRAM cells in a majority of the plurality of bit cells have the second state and Complement MRAM cells in a corresponding majority of the plurality of bit cells have the first state, while the True MRAM cell in at least one of the plurality of bit cells has the first state and the Complement MRAM cell in the at least one of the plurality of bit cells has the second state.

In some implementation examples, the non-volatile memory further comprises first and second power supply terminals configured to be coupled to first and second power supply voltages, respectively. The respective read sense amplifier includes a respective current sense amplifier configured to source a first current and a second current from the first power supply terminal, and to output a pair of signals based on a difference between the first current and the second current, the first current corresponding to a sum of a plurality of branch currents through respective True MRAM cells in the plurality of bit cells, the second current corresponding to a sum of a plurality of branch currents through respective Complement MRAM cells in the plurality of bit cells.

In some implementation examples, the respective write driver includes a first current path and a second current path, and wherein the first current is conducted from the respective current sense amplifier to the True bit line of the respective pair of bit lines via the first current path, and the second current is conducted from the respective current sense amplifier to the Complement bit line of the respective pair of bit lines via the second current path.

In some implementation examples, the respective write driver further includes a third current path and a fourth current path. The first current is further conducted from the True source line of the respective pair of source lines to the second power supply terminal via the third current path, and the second current is further conducted from the Complement source line of the respective pair of source lines to the second power supply terminal via the fourth current path.

In some implementation examples, the first current path includes a first read pass gate configured to receive the first current from the respective current sense amplifier and first driver circuitry configured to drive the first current to the True bit line of the respective pair of bit lines. The second current path includes a second read pass gate configured to receive the second current from the respective current sense amplifier and second driver circuitry configured to drive the second current to the Complement bit line of the respective pair of bit lines.

In some implementation examples, the respective current sense amplifier includes a plurality of diode-connected transistors. Each of the plurality of diode-connected transistors is configured to source an equal fraction of the current from the power supply terminal. The respective current sense amplifier further includes a plurality of current drivers configured to drive the current to the respective bit cell block, wherein each of the plurality of N-type MOSFETs is configured to drive an equal fraction of the current.

A method of reading from a bit in a non-volatile memory according to some implementation examples comprises driving at least one current through one bit cell block storing the bit in the non-volatile memory, converting the at least one current into at least one voltage signal, and outputting a digital value base on the at least one voltage signal. The non-volatile memory including a plurality of bit cell blocks arranged in at least one row and a plurality of columns, each bit cell block of the plurality of bit cell blocks including a plurality of bit cells configured to store one data bit having a bit value of “1” or “0”. Each of the at least one current corresponds to a sum of a plurality of branch currents through respective ones of the plurality of bit cells of the one bit cell block.

In some implementation examples, each bit cell of the plurality of bit cells includes a True cell and a Complement cell, and the at least one current includes a first current corresponding to a sum of a first plurality of branch currents through respective True cells in the one bit cell block and a second current corresponding to a sum of a second plurality of branch currents through respective Complement cells in the one bit cell block. The first current and the second current are converted into differential voltage outputs that are used to determine the digital value.

In some implementation examples, driving the at least one current through the one bit cell block comprises sourcing a first current from a power supply using a plurality of diode-connected transistors, each of the plurality of diode-connected transistors to source an equal fraction of the first current from the power supply, and driving the first current to the one bit cell block using a plurality of current drivers, each of the plurality of current drivers to drive an equal fraction of the first current.

### BRIEF DESCRIPTION OF THE DRAWINGS

FIG. 1 is a simplified high level block diagram of a non-volatile 3-bit status register array with status register write and read control, showing each bit of the status register array corresponding to a n×p STT-MRAM cell array, according to the present disclosure.

FIGS. 2A and 2B are diagrams of a n×p bit cell block representing 1 status register bit shown in FIG. 1, for the case of n=4, p=2, according to the present disclosure.

FIGS. 3A to 3C are diagrams of a write driver with read pass gate according to the present disclosure.

FIGS. 4A-4C are circuit diagrams of a current sense amplifier configured to sense a sum of currents through multiple MRAM cells in a status register bit according to the present disclosure.

FIG. 5 is a circuit diagram of a cross-coupled voltage sense amplifier according to the present disclosure.

FIG. 6 is a diagram of a read sense amplifier according to the present disclosure.

FIGS. 7A and 7B are diagrams illustrating a read current path through multiple MRAM cells in a status register bit according to the present disclosure.

FIGS. 8-11 are waveform diagrams illustrating read operations for reading a status register bit including a plurality of MRAM cells in the cases of 0-bit fail, 1-bit fail, 2-bit fail and 3-bit fail, respectively, according to the present disclosure.

### DETAILED DESCRIPTION OF THE EMBODIMENTS

Control registers are typically included in memory devices and microprocessors to provide high-speed storage locations that manage, configure, and monitor the behavior of hardware components, such as memory management units (MMUs), peripheral devices, or CPU operation modes, etc. They enable essential tasks like enabling interrupts, setting data transfer modes, and controlling memory paging. A serial peripheral interface (SPI) is a communication protocol used to transfer data between microcontrollers, sensors, and other peripheral devices.

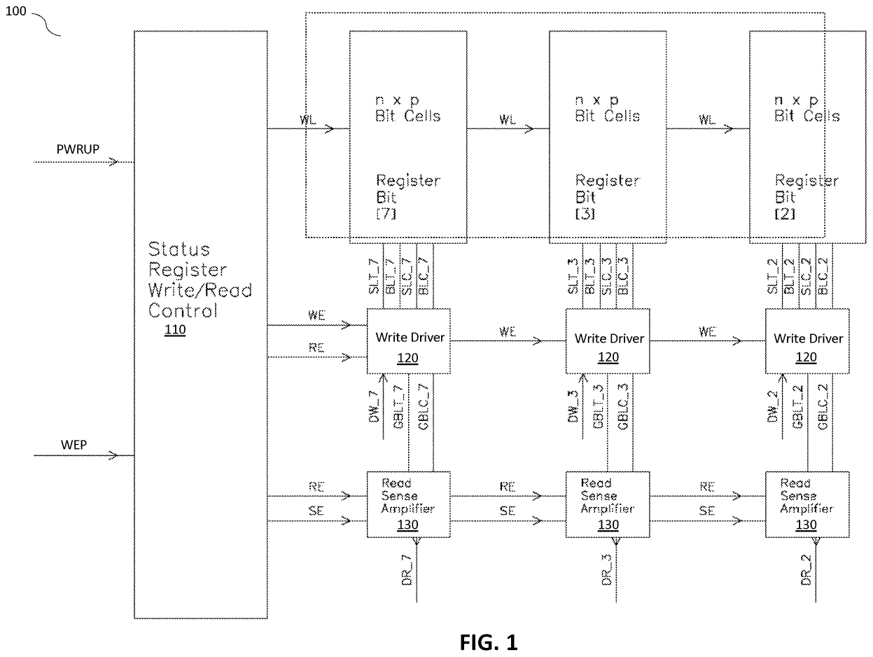

An SPI register provides dedicated non-volatile bits to store information about the current state of an SPI controller, such as whether a transfer is in progress, if data is available, or if an error has occurred. The number of bits in an SPI status register can vary, but commonly it's an 8-bit register, and at least some (e.g., 3) of the 8 bits are non-volatile bits. These non-volatile (NV) bits can be implemented using STT-MRAM (or MRAM) bit cells, as shown in FIG. 1, which is a simplified diagram of a status register array 100 controlled by a status register write/read control block 110. The status register array 100 includes an array of non-volatile (NV) status register bits arranged in at least one row and a plurality of columns. FIG. 1 illustrates an example where status register bits (e.g., register bit [0], register bit [1], . . . register bit [7]) in the status register array 100 are arranged in 1 row and 8 columns. The NV status register bit(s) in each column is coupled to a respective write driver 120 via a complementary pair of bit lines (BLT and BLC) and a complementary pair of source lines (SLT and SLC). The respective write drive is in turn coupled to a respective read sense amplifier 130 via a complementary pair of global bit lines (GBLT and GBLC). The write driver 120 receives control signals WE and RE from the status register write/read control block 110 and has a write date input DW. The read sense amplifier 130 receives control signals RE and SE from the status register write/read control block 110 and has a read data output DR. The array of status register bits includes at least one row of status register bits, and each row of status register bits are coupled to the status register write/read control block 110 via a common wordline (WL). As discussed further below, each status register bit includes a cell block of n×p non-volatile bit cells or cells, where n and p are positive integers.

In some implementation examples, each bit cell includes at least one memory cell or cell (e.g., an STT-MRAM or MRAM cell). As discussed above, the probability of write failures in STT-MRAM cells depends on the process and the stochastic behavior of the MTJ structures. Some process can have very high write error rate (WER). Therefore, the probability of a write failure in an MRAM cell can be high. To protect against write failures, multiple or redundant cells are used to represent a single register status bit according to certain implementation examples. When writing, the same data is written to all the bit cells in a cell block. When reading, a weighted sum of branch currents from all the bit cells in the cell block is used by the current sense amplifier to detect the single-bit value stored in the cell block so that in case some bits failed, read data can still be sensed correctly.

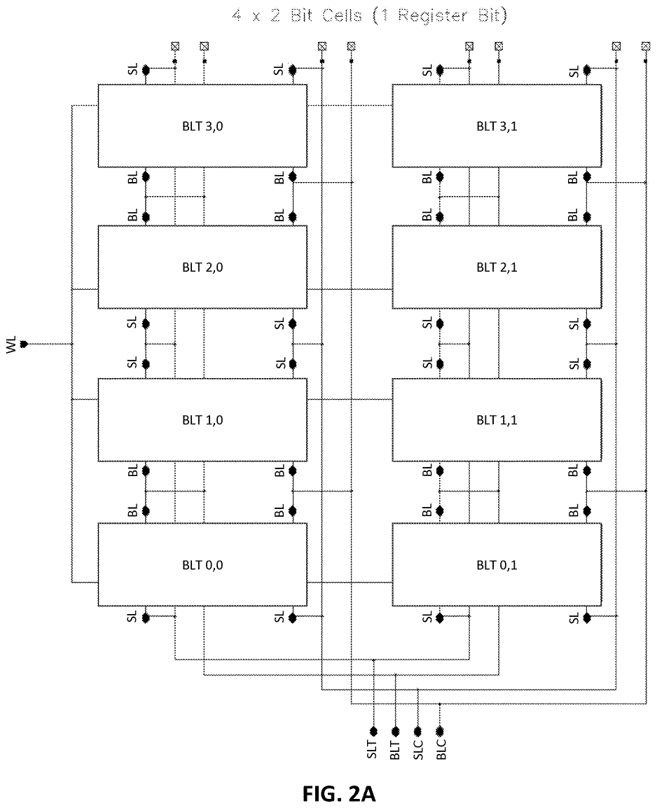

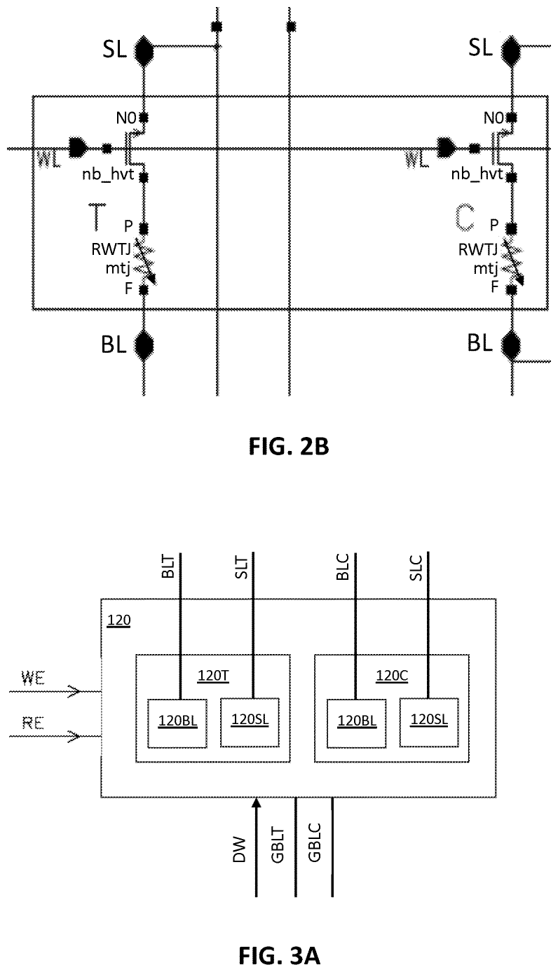

In some implementation examples, 8 (e.g., n=4, p=2) bit cells are used to form a cell block for each non-volatile register bit, as shown in FIGS. 2A and 2B. Each bit cell includes a complementary pair of a True cell (T) and a Complement cell (C), e.g., a True MRAM cell coupled to the T branch (BLT) of the bit line (BL) and the T branch (SLT) of the source line (SL), and a Complement MRAM cell coupled to the C branch (BLC) of the bit line (BL) and the C branch (SLC) of the source line (SL). Thus, in this implementation example, all 8 bit cells (e.g., bits [0,0], [1,0], [2,0], [3,0], [0,1], [1,1], [2,1], and [3,1]) in the cell block share the same word line (WL), all True cells in the 8 bit cells share the same SLT line and the same BLT line, and all Complement cells in the 8 bit cells share the same SLC line and the same BLC line. Normally, in a bit cell, True bit data stored in the True MRAM cell and Complement bit data stored in the Complement MRAM cell are inverse of each other.

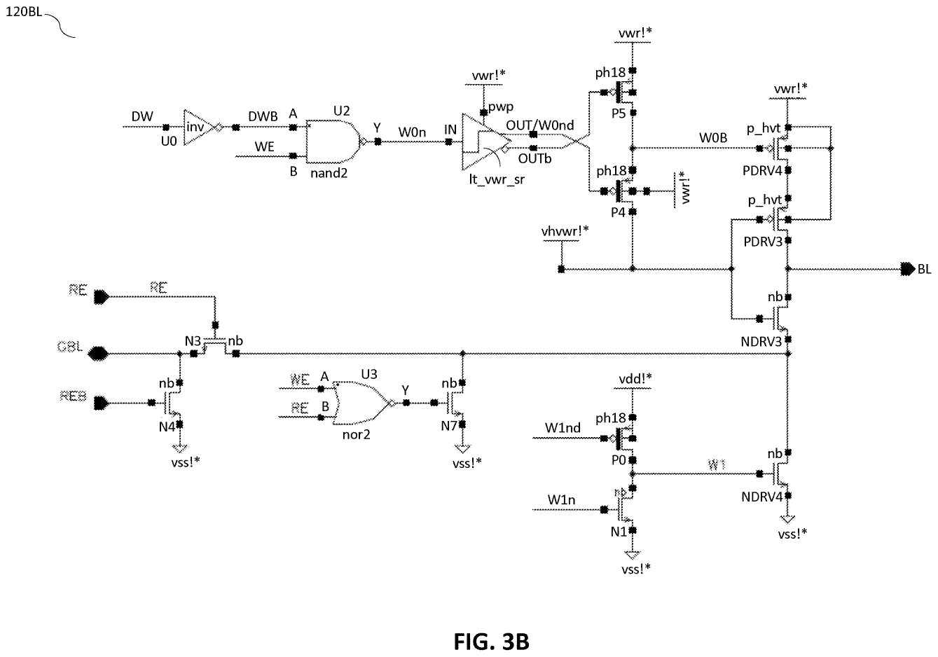

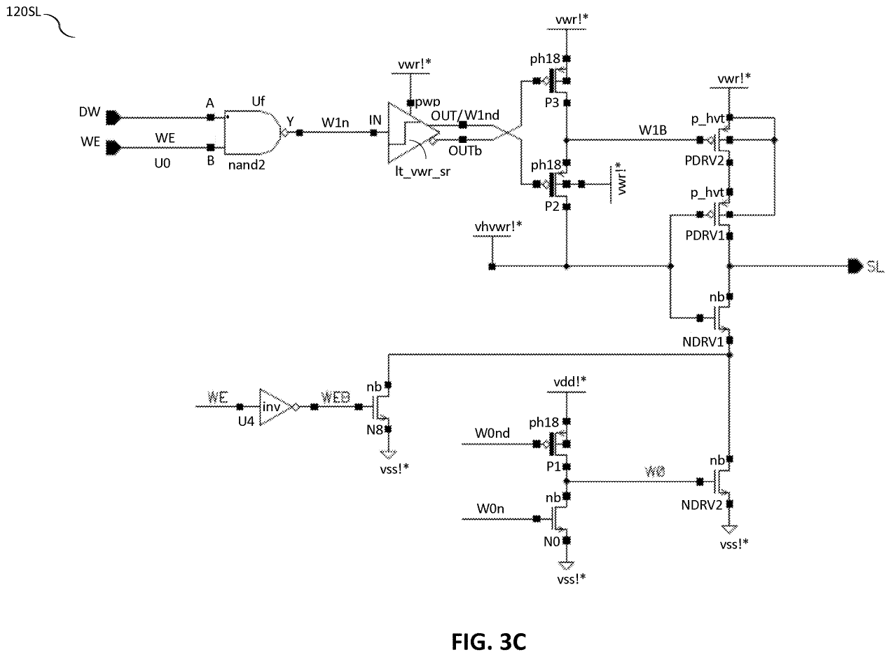

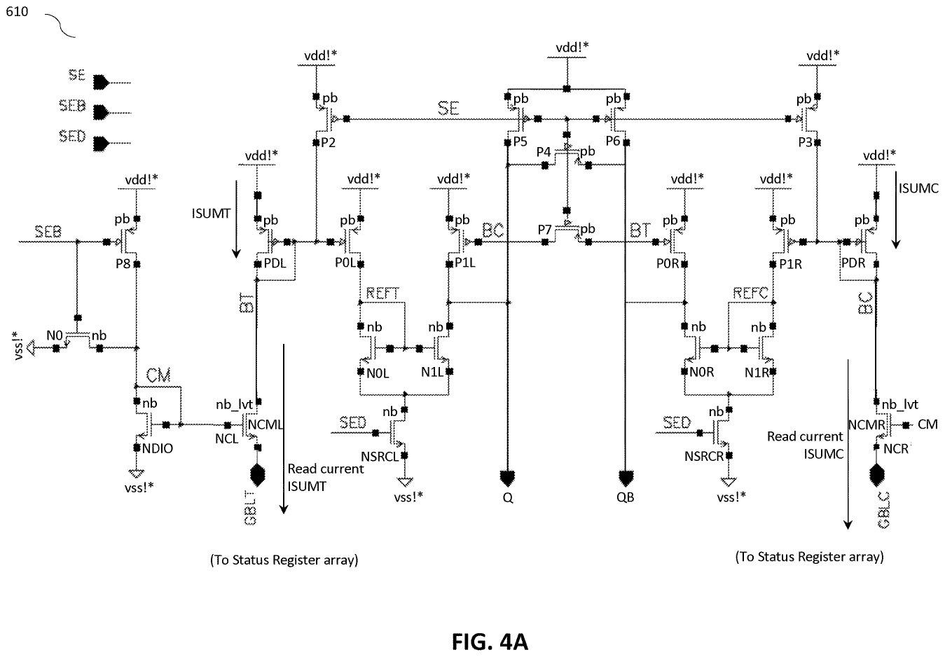

Accordingly, as shown in FIG. 3A, the write driver 120 coupled to the cell block includes a True driver 120T coupled to the True cells in the cell block via the BLT and SLT lines and a Complement driver 120C coupled to the Complement cells in the cell block via the BLC and SLC lines. The True driver 120T and the Complement driver 120C can be identical but are used to drive complementary bits. Each of the True driver 120T and the complementary driver 120C includes a bit line (BL) branch 120BL and a source line (SL) branch 120SL.

FIG. 3B shows a circuit implementation of a BL branch 120BL of a True driver 120T or Complement driver 120C according to certain implementation examples. The BL branch 120BL is used to drive the True bit lines (BLT) coupled to the True bit cells in a corresponding register bit cell block (e.g., the bit cell block shown in FIGS. 2A and 2B), or the Complement bit lines (BLC) coupled to Complement bit cells in the corresponding register bit cell block, e.g., the bit cell block shown in FIGS. 2A and 2B.

FIG. 3C shows a circuit implementation of an SL branch 120SL of a True driver 120T or Complement driver 120C according to certain implementation examples. The SL branch 120SL is used to drive the True source lines (SLT) coupled to the True bit cells in the corresponding register bit cell block, or the Complement source lines (SLC) coupled to Complement bit cells in the corresponding register bit cell block.

Each of the True driver 120T and Complement driver 120C is similar to the write driver described in commonly owned U.S. patent application Ser. No. 19/572,853, filed Mar. 19, 2026, which is incorporated herein by reference in its entirety.

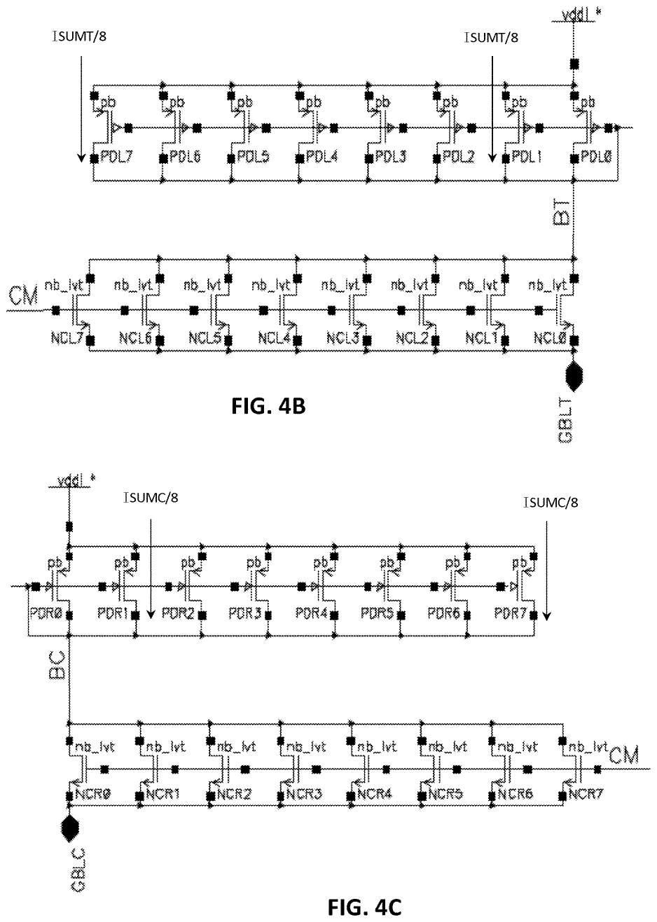

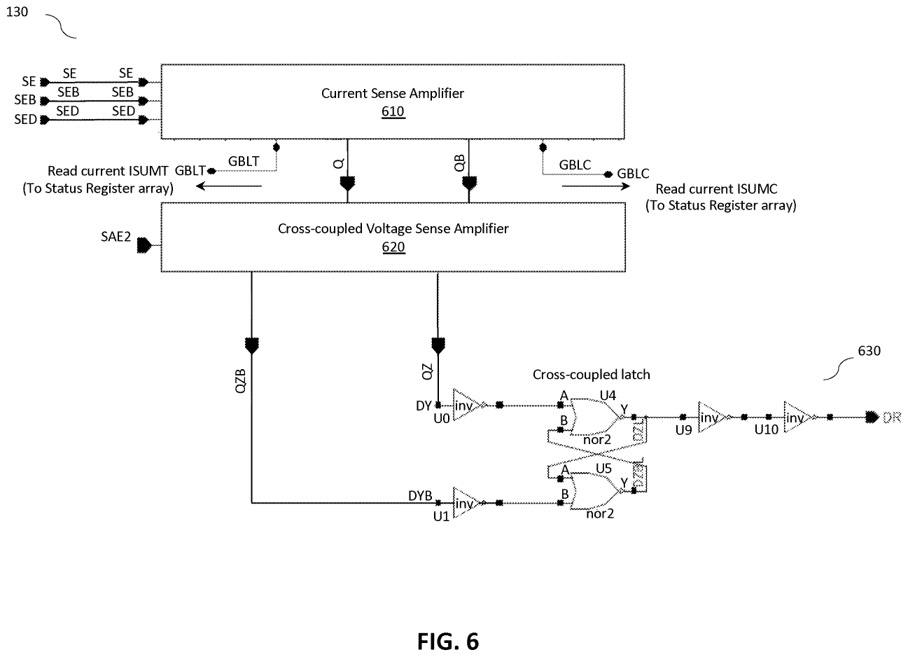

FIGS. 4A-6 illustrates a read sense amplifier 130 coupled to the write driver 120, as shown in FIG. 1, according to certain implementation examples. The read sense amplifier 130 is similar to the read sense amplifier described in commonly owned U.S. patent application Ser. No. 19/363,553, filed Oct. 20, 2025, which is incorporated herein by reference in its entirety. As shown in FIG. 6, the Read sense amplifier 130 includes a current sense amplifier 610, a cross-coupled voltage sense amplifier 620 coupled to complementary outputs Q and QB of the current sense amplifier 610, and a cross-coupled latch and inverter driver circuit 630 coupled to complementary outputs QZ and QZB of the cross-couple voltage sense amplifier 620. As shown in FIGS. 4A-4C and discussed further below, the current sense amplifier 610 receives currents from the bit cells in a corresponding cell block, and uses sums of the currents to sense a bit value stored in the cell block.

As shown in FIGS. 3B-6, the write drivers and read sense amplifiers are coupled to the same power/voltage terminals, which include:
VDD (or vdd!)—Internal core voltage (e.g., 0.9V).
VSS (or vss!)—Ground (e.g., 0V).

Also, the following signals are related to the operation of the status register array 100 according to some implementation examples.
PWRUP—Power Up signal. After VDD is driven to its core voltage level of 0.9 v, PWRUP goes high to indicate that the internal core voltage is up and ready. PWRUP also generates RE, a read enable control signal to enable reading data from the status register array.
WEP—Write enable pulse. WEP triggers a write operation to the status register array and generates WE, a write enable control signal.
WE—Write enable control signal for the write drivers during write operation.
RE—Read enable control signal for the Read pass gate and sense amplifier during read operation.
SE—Sense amplifier enable signal for the current sense amplifier.
SEB—Inverse of SE.
SED—Delayed SE signal for the current sense amplifier.
SE2—Sense amplifier enable signal for the cross-coupled voltage sense amplifier.
CM—An analog voltage clamp signal for controlling the gate level of the GBL pass gate to the input the current sense amplifier to prevent a read disturb.
BT, BC—Internal current sense amplifier nodes. The MTJ current drives the level of these nodes. T is a naming associated with the True bit cell while C is associated with the Complement bit cell.
REFT, REFC—Internal reference nodes for sense amplifiers.
WL—Word line. WL is connected the gate of the access transistor of the memory cell. This signal is usually a boosted to a high voltage level, for example, 2.0 v.
DW—Write data. Data to be written to the memory cells.
DWB—Inverse of DW.
SL—Source line data. When writing a ‘1’, SL is driven to VWR level. When writing a ‘0’, SL is driven to VSS level.
BL—Bit line data. When writing a ‘1’, BL is driven to VSS level. When writing a ‘0’, BL is driven to VWR level.
ISUM—Summation of all the Read current components to the status register array bit cells.

As shown in FIG. 4A, current sense amplifier 610 has control inputs SE, SEB, and SED to receive SE, SEB, and SED control signals, respectively, and complementary outputs Q and QB. SE represents the sense amplifier enable signal, SEB is the inverse of SE, and SED is a delayed version of SE. The current sense amplifier 610 also includes terminals GBLT and GBLC coupled to a corresponding write driver via a pair of bidirectional True and Complement global bit lines, GBLT and GBLC, respectively, as shown in FIG. 1.

As shown in FIG. 4A, the current sense amplifier 610 includes interconnected transistors, among which: transistors P8 and NDIO together generates a clamp voltage CM; transistors P2, P3, and P7 are for pre-charging and equalizing the BT and BC nodes to VDD; transistors P4, P5, and P6 are for pre-charging and equalizing Q and QB to VDD; transistors POL, PIL, NOL, NIL form a P type differential amplifier on the left of the figure; transistors POR, PIR, NOR, NIR form another P type differential amplifier on the right; NSRCL and NSRCR are transistors that can be used to enable or disable the amplifiers; transistors NCML, NCMR are clamp transistors and function to limit the voltage swing on GBLT/GBLC so that it does not cause read disturb that ends up flipping the MTJ state of any cell during a read operation. Transistors NCML and PDL form a common stage amplifier with a PMOS diode connected load for the GBLT line; and transistors NCMR and PDR form an amplifier of the same stage with a PMOS diode connected load for the GBLC line. Further description of the transistors (NCML, NCMR) can be found in commonly owned U.S. patent application Ser. No. 19/363,553, filed Oct. 20, 2025, which is incorporated herein by reference in its entirety. The output of left and right amplifiers are Q and QB, respectively.

During a read operation, SE is brought high forcing SEB to be brought low, which turns off NO. P8 and NDIO become a diode connected reference circuit to generate the clamp voltage CM at around 0.55 v. This CM at the gate prevents NCML and NCMR from fully turning on and also prevents the GBLT and GBLC level from going too high where they may unintentionally flip the data in memory cells, a situation known as a read disturb. Additionally, during the read operation, SE being high disables P2, P3, P7, P4, P5, P6. As a result, BT, BC, Q and QB are no longer being pre-charged. These nodes are ready to be driven.

Once SE is asserted high and CM is brought high, NCML and NCMR are on. The read current path from the current sense amplifier 610 is enabled. As shown in FIG. 4A, the read current via NCML is ISUMT and the read current via NCMR is ISUMC. As stated previously, the data on GBLT and GBLC lines should be complementary. So, there are two possible cases when the current sense amplifier 610 is used to read from just one pair of True and Complement MRAM cells:
1. GBLT is connected to a memory cell with the MTJ resistance state Rp and GBLC is connected to a memory cell with MTJ resistance state Rap; or
2. GBLT is connected to a memory cell with the MTJ resistance state Rap and GBLC is connected to a memory cell with MTJ resistance state Rp.

Here, Rp is the low resistance state, and Rap is high resistance state. Thus, in case 1, GBLT is connected to a memory cell with MTJ resistance state Rp (equivalent to reading a ‘0’ from the memory cell), GBLC is connected to a memory cell with MTJ resistance state Rap (equivalent to reading a ‘1’ from the memory cell). Since GBLT path is associated with Rp, the read current on GBLT path is higher than the current on GBLC, or ISUMT>ISUMC. Conversely, in case 2, GBLT is connected to a memory cell with MTJ resistance state Rap (equivalent to reading a ‘1’ from the memory cell), GBLC is connected to a memory cell with MTJ resistance state Rp (equivalent to reading a ‘0’ from the memory cell). Thus, the read current on GBLT path is lower than the current on GBLC, or ISUMT<ISUMC.

The next stage is a P type differential input amplifier. The inputs are BT and BC, and the outputs are Q and QB. In the case of ISUMT>ISUMC, BT is pulled slightly lower than BC. This means that v(BT)<v(BC), the voltage level of BT is slightly lower than the voltage level of BC. The opposite can be said for the case when ISUMT<ISUMC. Once the BT and BC level is established and stabilized, SED is brought high, which turns on NSRCL and NSRCR to conduct current and enable the differential amplifiers.

In some implementation examples, the current sense amplifier 610 is used to read from multiple pairs of True and Complement MRAM cells, as shown in FIGS. 2A-2C. ISUMT via GBLT and ISUMC via GBLC are read current going to the corresponding cell block in the status register array. ISUMT is associated with the True bit cells in the cell block and ISUMC is associated with the Complement bit cells in the cell block. As discussed above, NCML and PDL form a common stage amplifier with PMOS diode connected load for the GBLT line. NCMR and PDR form an amplifier of the same stage for GBLC line. PDL and PDR are the PMOS diode connected loads. The inputs to this amplifier stage are the currents ISUMT and ISUMC, respectively, rather than voltages. The outputs of this stage are BT and BC voltages. Therefore, this amplifier stage takes the currents as inputs and converts them to voltages as outputs.

As shown in FIGS. 4B and 4C, in some implementation examples, each PMOS diode load (PDL, PDR) have 8 branches (PDL0-PDL7, PDR0-PDR7), and each NMOS transistor (NCML, NCMR) have 8 branches (NCL0-NVL7, NCR0-NCR7, i.e., one branch for each MTJ cell in a register bit). Each branch current through a respective branch of PDL or PDR represents ⅛ of ISUMT or ISUMC, respectively. All branch currents are equal and have equal weight. Although 8 branches (i.e., one branch for each MTJ cell) are provided for a register bit in some implementation examples, the PMOS diode load (PDL, PDR) can have more or less than 8 branches as long as it is capable of reliably sourcing sufficient current for the 8 MRAM cells. Each of the transistors (NCML, NCMR) can have more or less than 8 branches. In some implementation examples, having 8 branches in each of the transistors (NCML, NCMR) helps to ensure that data can be properly read even when 1 or 2 branches fail, as the weight of the other 6 or 7 passing cells/branches can outweigh the failing branch(es) to force a passing READ.

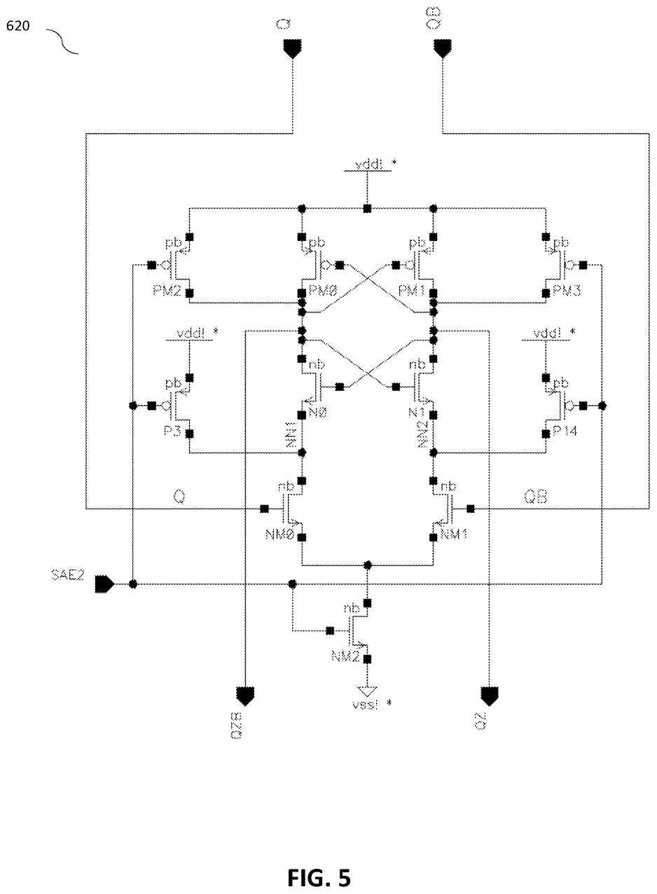

FIG. 5 shows a circuit implementation of a cross-coupled voltage sense amplifier 620 according to some implementation examples. The cross-coupled voltage sense amplifier 620 is configured to further amplifier the differential outputs (Q, QB) from the differential amplifier in the current sense amplifier 610 and to convert the differential outputs Q and QB to digital outputs (QZ, QZB) at digital levels, 0 or 1 (VDD level). Once the differential outputs (Q and QB) from the current sense amplifier 610 are ready, SAE2 is asserted, then QZ and QZB are driven to near rail to rail level according to Q and QB.

In some implementation examples, a Read operation to read from one of the status register bits in the status register circuit 100 can be described as follows.

Initially, referring to FIG. 4A, during an idle or pre-charge state, SE=low and that forces SEB=high, which turns on NO, which drives CM to VSS. As a result, both NCML and NCMR are turned off. This cuts off the read current path via CBLT and/or CBLC from the current sense amplifier 610 to the corresponding status bit. Further, SE=low enables P2, P3, P7, which pre-charge node BT and BC to VDD, and SE=low also enables P4, P5, P6, which pre-charge Q and QB to VDD.

During a read operation (referring to FIG. 4A), SE is brought high forcing SEB to be brought low, which turns off NO. P8 and NDIO become a diode connected reference circuit to generate the clamp voltage CM at around 0.55 v. This CM at the gate prevents NCML and NCMR from fully turning on and prevents the GBLT and GBLC level from going too high where they may unintentionally flip the data in memory cells, a situation known as a read disturb. Additionally, during the read operation, SE being high disables P2, P3, P7, P4, P5, P6. As a result, BT, BC, Q and QB are no longer being pre-charged. These nodes are ready to be driven. Further, once SE is asserted high and CM->high, NCML and NCMR are on. First and second read current paths from the current sense amplifier to the status register array are enabled.

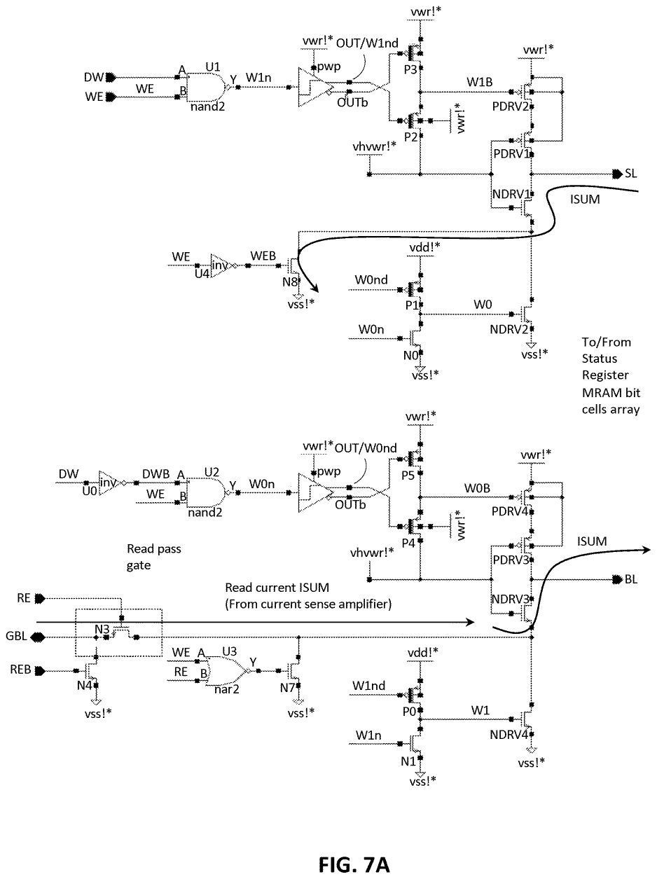

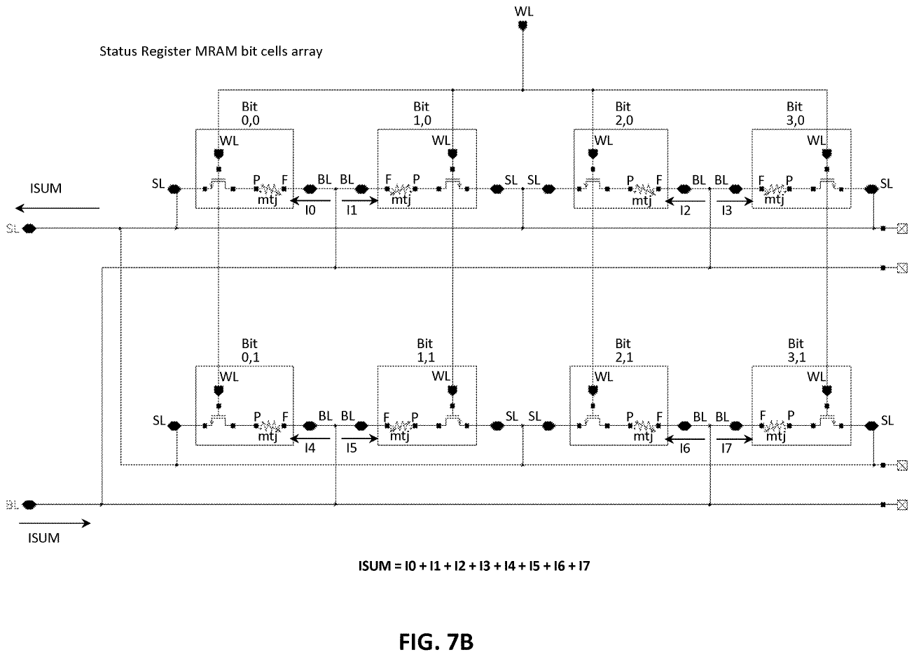

FIGS. 7A and 7B illustrate the first (or second) read current paths from the current sense amplifier 610 to a corresponding status register cell block that uses a n×p MRAM array to store a single status register bit according to certain implementation examples. As shown in FIG. 7A, ISUM (ISUMT or ISUMC), which is a read current from the current sense amplifier, goes through N3 (Read pass gate) and NDRV3 (of the Write Driver) and through a BL node at the edge of the MRAM array.

As shown in FIG. 7B, when ISUM enters the MRAM array, it splits up into 8 branch currents (labeled as I0-I7) that enter respective ones of the 8 MTJs in bit cells [0,0], [1,0], [2,0], [3,0], [0,1], [1,1], [2,1], and [3,1]). So,

ISUM=I0+I1+I2+I3+I4+I5+I6+I7.

Unlike the branch currents through different branches of the PDL, PDR, NCL or NCR transistor, which can be made equal by using identical branch transistors in the PDL, PDR, NCL or NCR transistor, the value of each branch current I0 to I7 through a respective MRAM cell depends on the MTJ resistance state, Rp or Rap, in the respective MRAM cell. If the MTJ is Rp, then the branch current is higher. If the MTJ is Rap, then the branch current is lower. Therefore, the weight of each branch current is dependent on the MTJ resistance state, and the current ISUM, which is the sum of the branch currents I0 to I7, is dependent on the weight of each current branch.

After ISUM passes through the MTJ and the cell access transistors, it exits the MRAM array through the SL node. From the SL node, ISUM returns through NDRV1 (of the Write Driver) and through N8 (which pre-charges SL to VSS during a read operation) and then to VSS. This completes the read current path from read power source at PDIO diode-connected load (PDL and PDR) in the current sense amplifier) to the VSS at the SL.

Current sensing using weighted sum current, in the implementation examples described herein with reference to FIGS. 4 to 11, is described below for 4 different cases, where the current sensing method using weighted sum current is used to generate the correct output data DR despite that there could be one or more failed bits.

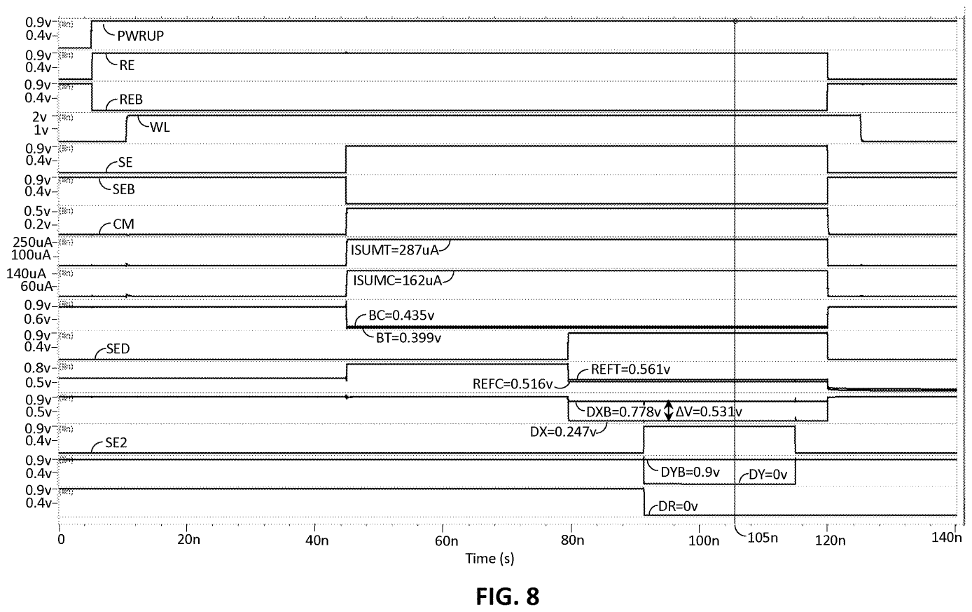

### Case #1: 0 Bit Fail (Corresponding to Waveform Diagram Shown in FIG. 8)

If the initial resistance state (Rp or Rap) of MTJ is the same for all 8 bit cells, then the branch current through different MTJ bit cells can be determined and would have equal value (or equal weight in ISUM).

Referring to FIG. 8, which is a waveform diagram showing the case of a read operation, where initially all True bit cells (T) are Rp and all Complement bit cells (C) are Rap in a cell block. This means there are no errors and no bit fails and the same True and Complement data have been written successfully to all 8 True and Complement bit cells.

Assuming that initially, all 8 True cells are Rp and 8 Complement cells are Rap (FIG. 2). This means there are 0 bit fails. In this case (referring to FIG. 8), ISUMT=287 mA, ISUMC=162 mA, as shown in the waveform diagram of FIG. 8. Thus, ISUMT>ISUMC, forcing BT (0.399 v)<BC (0.435 v) in the current sense amplifier of FIG. 4. Each branch current at the BT and BC nodes would have equal weight ISUMT/8 and ISUMC/8 respectively. This means I(Rp)=287 mA/8=35.9 mA and I(Rap)=162 mA/8=20.3 mA. Based on this I(Rp) and I(Rap) calculation, each branch current or component (I0-I7) of ISUM in FIG. 7 is weighted as:

I=35.9 mA if the MTJ is RP

I=20.3 mA if the MTJ is Rap.

The current sense amplifier detects and senses the weighted sum of the read current (ISUMT and ISUMC) and generates a small differential voltage output BT, BC. Any change or difference in the weight would manifest as the difference in the magnitude of the differential output BT, BC. BT<BC would force REFT (0.561 v)>REFC (0.516 v) and this generates a differential output (DX, DXB) of 0.531 v. After the cross-coupled voltage sense amplifier stage, the output DY=0, DYB=0.9 v. After the latch, output DR=0 v, which is the correct data because the True cells are Rp (equivalent to 0).

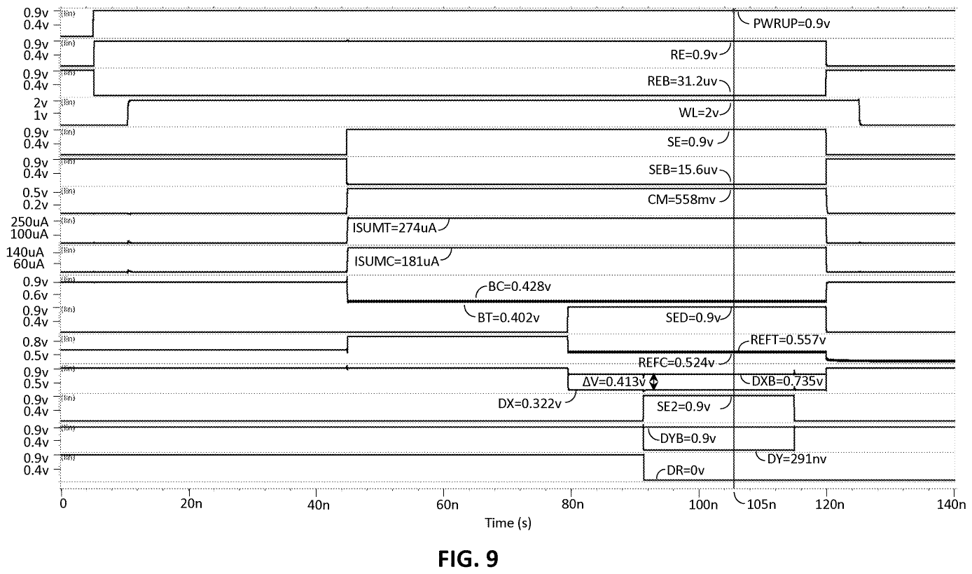

### Case #2: 1 Bit Has Failed (Corresponding to Waveform Diagram Shown in FIG. 9)

In this case, 1 out of 8 True cells is Rap (the other 7 True cells are Rp), and 1 out of 8 Complement cells is Rp (the other 7 Complement cells are Rap).

ISUMT=274 mA, ISUMC=181 mA. The weighted sum current ISUMT is approximately equal to 1*I(Rap)+7*I(Rp). The weighted sum current ISUMC is approximately equal to 1*I(Rp)+7*I(Rap). Recalled that I(Rp)=35.9 mA and I(Rap)=20.3 mA.

With 1 bit having failed, BT (0.402 v)<BC (0.428 v) and REFT (0.557 v)>REFC (0.524 v). A reasonable differential output (DX, DXB) of 0.413 v is generated. However, this differential output is smaller than the 0 bit fail case. DY=0, DYB=0.9 v, and DR=0 v (the correct data).

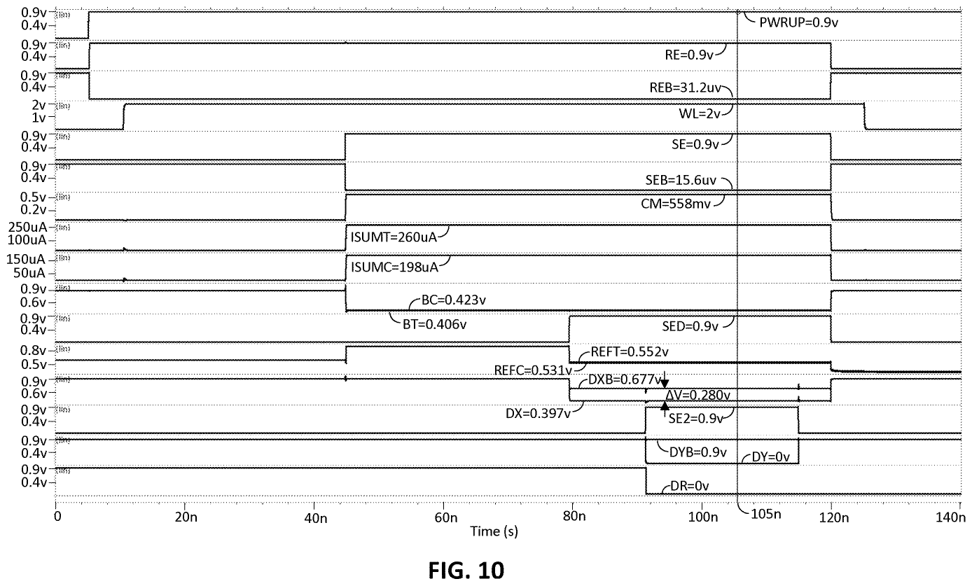

### Case #3: 2 Bits Have Failed (Corresponding to Waveform Diagram Shown in FIG. 10)

In this case, 2 out of 8 True cells are Rap, the other 6 True cells are Rp, and 2 out of 8 Complement cells are Rp, the other 6 Complement cells are Rap.

ISUMT=260 mA, ISUMC=198 mA. The weighted sum current ISUMT is approximately equal to 2*I(Rap)+6*I(Rp). The weighted sum current ISUMC is approximately equal to 2*I(Rp)+6*I(Rap).

With 2 bit having failed, BT (0.406 v)<BC (0.423 v) and REFT (0.552 v)>REFC (0.531 v). A reasonable differential output (DX, DXB) of 0.280 v is still generated. However, this differential output is smaller than the 1 bit fail case. Nonetheless, DY=0, DYB=0.9 v, and DR=0 v (the correct data).

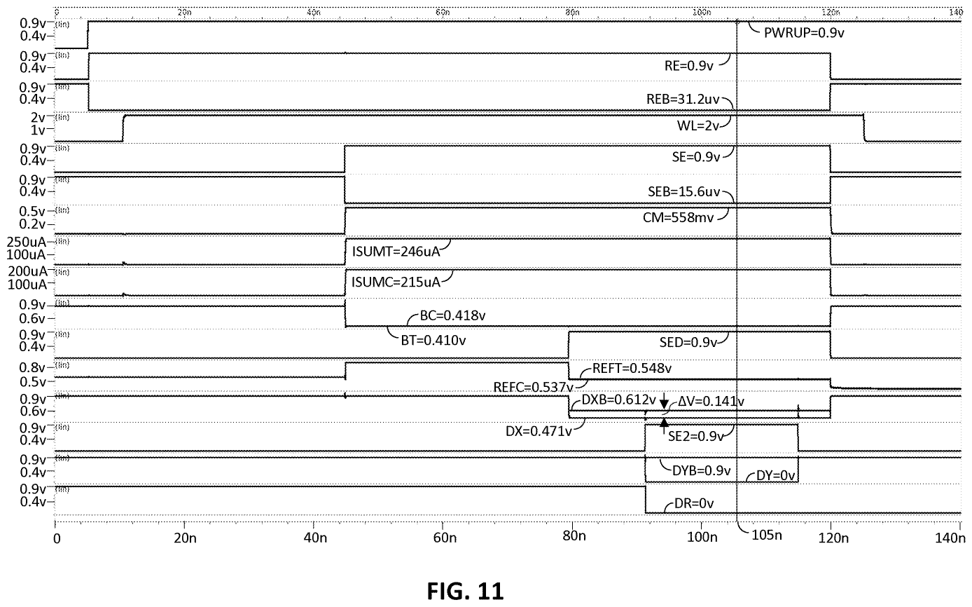

### Case #4: 3 Bits Have Failed (Corresponding to Waveform Diagram Shown in FIG. 11)

In this case, 3 out of 8 True cells are Rap, the other 5 True cells are Rp, and 3 out of 8 Complement cells are Rp, the other 5 Complement cells are Rap.

ISUMT=246 mA, ISUMC=215 mA. The weighted sum current ISUMT is approximately equal to 3*I(Rap)+5*I(Rp). The weighted sum current ISUMC is approximately equal to 3*I(Rp)+5*I(Rap).

Thus, with 3 bits having failed, BT (0.410 v)<BC (0.418 v) and REFT (0.548 v)>REFC (0.537 v). A differential output (DX, DXB) of 0.141 v is generated. This differential output is further reduced and smaller than the other bit fail cases but still sufficient to generate the correct output data, as DY=0, DYB=0.9 v, and DR=0 v (the correct data).

The description of the different examples of implementations has been presented for purposes of illustration and description, and is not intended to be exhaustive or limited to the examples in the form disclosed. Many modifications and variations will be apparent to those of ordinary skill in the art. Further, different examples of implementations may provide different features as compared to other desirable examples. The example, or examples, selected are chosen and described in order to best explain the principles of the examples, the practical application, and to enable others of ordinary skill in the art to understand the disclosure for various examples with various modifications as are suited to the particular use contemplated.

The terminology used in the description of the various described implementation examples herein is for the purpose of describing particular implementation examples only and is not intended to be limiting. As used in the description of the various described implementation examples and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

1. A non-volatile memory, comprising:
a plurality of bit cell blocks arranged in at least one row and a plurality of columns, each bit cell block of the plurality of bit cell blocks including a plurality of bit cells configured to store one data bit having a bit value of “1” or “0”; and
a plurality of read sense amplifiers, a respective read sense amplifier of the plurality of read sense amplifier including a current sense amplifier coupled to each bit cell block in a respective column of the plurality of columns, and wherein, in an operation to read a bit value stored in one bit cell block in the respective column, the respective current sense amplifier is operable to source a current corresponding to a sum of a plurality of branch currents through respective ones of the plurality of bit cells of the one bit cell block.

2. The non-volatile memory of claim 1, wherein each bit cell of the plurality of bit cells includes a True cell and a Complement cell, and the respective current sense amplifier includes a first common stage amplifier operable to source a first current corresponding to a sum of a first plurality of branch currents through respective ones of a plurality of True cells in the one bit cell block and a second common stage amplifier operable to source second current corresponding to a sum of a second plurality of branch currents through respective ones of a plurality of Complement cells in the one bit cell block.

3. The non-volatile memory of claim 2, wherein the respective current sense amplifier is configured to convert the first current and the second current into differential voltage outputs that are used to determine the bit value stored in the one bit cell block.

4. The non-volatile memory of claim 2, further comprising:
at least one word line, wherein each word line of the at least one wordline is coupled to bit cell blocks in a respective row of the at least one row;
a plurality of pairs of bit lines corresponding, respectively, to the plurality of columns, each pair of bit lines of the plurality of pairs of bit lines including a True bit line and a Complement bit line; and
a plurality of pairs of source lines corresponding, respectively, to the plurality of columns, each pair of source lines of the plurality of pairs of source lines including a True source line and a complementary source line; wherein:
a respective bit cell block of each row of bit cell blocks is coupled to a corresponding word line of the at least one word line, to a respective pair of bit lines of the plurality of pairs of bit lines and to a respective pair of source lines of the plurality of pairs of source lines;
each bit cell in the respective bit cell block includes a complementary pair of Magnetoresistive Random Access Memory (MRAM) cells, the complementary pair of MRAM cells including a True MRAM cell and a Complement MRAM cell, each MRAM cell of the True MRAM cell and Complement MRAM cell including a Magnetic Tunnel Junction (MTJ) structure and a select transistor coupled in series;
the select transistor in the each MRAM cell has a control terminal coupled to the corresponding word line;
the True MRAM cell is coupled between the True source line of the respective pair of source lines and the True bit line of the respective pair of bit lines; and
the Complement MRAM cell is coupled between the complementary source line of the respective pair of source lines and the complementary bit line of the respective pair of bit lines.

5. The non-volatile memory of claim 4, further comprising a plurality of write drivers corresponding, respectively, to the plurality of columns, wherein a respective write driver of the plurality of write drivers is coupled to the respective bit cell block via the respective pair of bit lines and the respective pair of source lines.

6. The non-volatile memory of claim 5, wherein the respective current sense amplifiers is coupled to the respective write driver via a pair of global bit lines, and wherein the respective current sense amplifier is operable to source the current that is the sum of currents through respective ones of the plurality of bit cells of the one bit cell block via a corresponding global bit line and the respective write driver.

7. The non-volatile memory of claim 2, wherein the respective read sense amplifier further includes a respective voltage sense amplifier coupled to the respective current sense amplifier and configured to amplifier the differential voltage outputs and to output amplified differential voltage outputs.

8. The non-volatile memory of claim 7, wherein the respective read sense amplifier further includes a respective latch and inverter driver circuit configured to convert the amplified differential voltage outputs into a digital bit value of “1” or “0”.

9. The non-volatile memory of claim 4, wherein:
a respective MRAM cell of the True MRAM cell and Complement MRAM cell has a first state or a second state depending on whether the MTJ structure in the respective MRAM cell has a first resistance state or a second resistance state;
the respective read sense amplifier is configured to sense the respective bit cell block as storing a data value of “0” in each of a first case and a second case;
in the first case, the True MRAM cell in each bit cell of the respective bit cell block has the first state and the Complement MRAM cell in each bit cell of the respective bit cell block has the second state;
in the second case, True MRAM cells in a majority of the plurality of bit cells have the first state and Complement MRAM cells in a corresponding majority of the plurality of bit cells have the second state, while the True MRAM cell in at least one of the plurality of bit cells has the second state and the Complement MRAM cell in the at least one of the plurality of bit cells has the first state.

10. The non-volatile memory of claim 3, wherein:
the respective read sense amplifier is further configured to sense the respective bit cell block as storing a data value of “1” in each of a third case and a fourth case;
in the third case, the True MRAM cell in each bit cell of the respective bit cell block has the second state and the Complement MRAM cell in each bit cell of the respective bit cell block has the first state; and
in the fourth case, True MRAM cells in a majority of the plurality of bit cells have the second state and Complement MRAM cells in a corresponding majority of the plurality of bit cells have the first state, while the True MRAM cell in at least one of the plurality of bit cells has the first state and the Complement MRAM cell in the at least one of the plurality of bit cells has the second state.

11. The non-volatile memory of claim 5, further comprising first and second power supply terminals configured to be coupled to first and second power supply voltages, respectively, wherein the respective current sense amplifier is configured to source a first current and a second current from the first power supply terminal, and to output a pair of voltage signals based on a difference between the first current and the second current, the first current corresponding to a sum of a plurality of branch currents through respective True MRAM cells in the plurality of bit cells, the second current corresponding to a sum of a plurality of branch currents through respective Complement MRAM cells in the plurality of bit cells.

12. The non-volatile memory of claim 11, wherein the respective write driver includes a first current path and a second current path, and wherein the first current is conducted from the respective current sense amplifier to the True bit line of the respective pair of bit lines via the first current path, and the second current is conducted from the respective current sense amplifier to the Complement bit line of the respective pair of bit lines via the second current path.

13. The non-volatile memory of claim 12, wherein the respective write driver further includes a third current path and a fourth current path, wherein the first current is further conducted from the True source line of the respective pair of source lines to the second power supply terminal via the third current path, and the second current is further conducted from the Complement source line of the respective pair of source lines to the second power supply terminal via the fourth current path.

14. The non-volatile memory of claim 13, wherein the first current path includes a first read pass gate configured to receive the first current from the respective current sense amplifier and first driver circuitry configured to drive the first current to the True bit line of the respective pair of bit lines; and wherein the second current path includes a second read pass gate configured to receive the second current from the respective current sense amplifier and second driver circuitry configured to drive the second current to the Complement bit line of the respective pair of bit lines.

15. The non-volatile memory of claim 1, further comprising a power supply terminal configured for connecting the non-volatile memory to a power supply, wherein the respective current sense amplifier includes a plurality of diode-connected transistors, wherein each of the plurality of diode-connected transistors is configured to source an equal fraction of the current from the power supply terminal.

16. The non-volatile memory of claim 15, wherein the respective current sense amplifier further includes a plurality of current drivers configured to drive the current to the respective bit cell block, wherein each of the plurality of N-type MOSFETs is configured to drive an equal fraction of the current.

17. A method of reading from a bit in a non-volatile memory, comprising
driving at least one current through one bit cell block storing the bit in the non-volatile memory, the non-volatile memory including a plurality of bit cell blocks arranged in at least one row and a plurality of columns, each bit cell block of the plurality of bit cell blocks including a plurality of bit cells configured to store one data bit having a bit value of “1” or “0”, wherein each of the at least one current corresponds to a sum of a plurality of branch currents through respective ones of the plurality of bit cells of the one bit cell block; and
converting the at least one current into at least one voltage signal; and
outputting a digital value base on the at least one voltage signal.

18. The method of claim 17, wherein each bit cell of the plurality of bit cells includes a True cell and a Complement cell, and the at least one current includes a first current corresponding to a sum of a first plurality of branch currents through respective True cells in the one bit cell block and a second current corresponding to a sum of a second plurality of branch currents through respective Complement cells in the one bit cell block.

19. The method of claim 17, wherein converting the at least one current into at least one voltage signal includes converting the first current and the second current into differential voltage outputs that are used to determine the digital value.

20. The method of claim 17, wherein driving the at least one current through the one bit cell block comprises:
sourcing a first current from a power supply using a plurality of diode-connected transistors, wherein each of the plurality of diode-connected transistors is configured to source an equal fraction of the first current from the power supply; and
driving the first current to the one bit cell block using a plurality of current drivers, wherein each of the plurality of current drivers is configured to drive an equal fraction of the first current.
